(19) United States
(12) Patent Application Publication
(10) Pub. No.: US 2011/0303284 A1
(43) Pub. Date: Dec. 15, 2011

(54) GLASS BARRIER FOR DIODE ASSEMBLIES

(75) Inventors: Chris Jongmin Kim, Santa Clara, CA (US); Daebong Lee, Sunnyvale, CA (US)

(73) Assignee: MIASOLE

(21) Appl. No.: 12/797,565

(22) Filed: Jun. 9, 2010

(51) Int. Cl. H01L 31/0203; H01L 31/18

(52) U.S. Cl. 136/259; 438/66; 257/E31.117

(57) ABSTRACT

A method and apparatus for protecting a diode assembly of a photovoltaic module from compressive forces, tensile forces, and solder migration by providing at least one localized glass barrier are provided. According to various embodiments, a photovoltaic module including a first encasing layer, a second encasing layer, at least one photovoltaic cell disposed between the first and second encasing layers, at least one shielded diode assembly disposed on the at least one photovoltaic cell and electrically connected to the at least one photovoltaic cell, and a pottant disposed between the at least one photovoltaic cell and the second encasing layer is provided. A localized glass barrier may be used to shield the diode assembly.

### FIELD OF THE INVENTION

The present invention relates generally to the field of photovoltaic devices, and specifically to shielding elements configured to provide protection to diode assemblies from compression forces.

### BACKGROUND OF THE INVENTION

Photovoltaic modules commonly comprise electrical components configured to connect photovoltaic cells to one another and to power-collecting devices.

### SUMMARY OF SPECIFIC EMBODIMENTS

One embodiment of the present invention provides a photovoltaic module comprising a first encasing layer, a second encasing layer, at least one photovoltaic cell disposed between the first and second encasing layers, at least one shielded diode assembly disposed on the at least one photovoltaic cell and electrically connected to the at least one photovoltaic cell, and a pottant disposed between the at least one photovoltaic cell and the second encasing layer, wherein the shielding material of the shielded diode assembly comprises glass.

Another embodiment of the present invention provides a method of shielding a diode assembly from compression forces by providing at least one shielding element in the form of a glass barrier fully encapsulating the leadframe portion of the diode assembly.

Another embodiment of the present invention provides a method of fabricating a photovoltaic module comprising a diode assembly protected by a glass barrier comprising providing a first encasing layer, positioning cells on a first encasing layer, providing protected diode assemblies, applying a pottant layer, positioning a second encasing layer and laminating the photovoltaic module assembly, wherein the protected diode assemblies comprise at least one localized glass barrier.

### BRIEF DESCRIPTION OF THE DRAWINGS

FIG. 1 is a cross-sectional view of a photovoltaic module comprising a diode assembly with external compression forces applied on the encasing layers.

FIG. 2 is a cross-sectional view of a photovoltaic module comprising a tensioned diode assembly and another photovoltaic module comprising a compressed diode assembly.

FIG. 3 is a cross-sectional view of a photovoltaic module comprising a diode assembly with a glass barrier disposed between a leadframe portion of the diode assembly and the second encasing layer.

FIG. 4 is a top view of a diode assembly with a glass barrier disposed on and around the leadframe portion of the diode assembly.

FIG. 5 is a flow diagram illustrating certain operations in a method of fabricating a photovoltaic module including a glass barrier shielding element according to certain embodiments.

### DETAILED DESCRIPTION OF PREFERRED EMBODIMENTS

Photovoltaic modules commonly comprise a plurality of photovoltaic cells that are electrically interconnected to each other and to energy-collecting circuitry to facilitate the collection of energy. Electrical interconnections that link photovoltaic cells to one another or to energy-collecting circuitry may comprise components such as diodes that are in electrical communication with further electrical components such as leads. In certain embodiments, a diode is connected to at least one lead which may be secured with at least one solder joint. For the purposes of the present disclosure, the diode and one or more leads and connecting joints, if present, will be termed a diode assembly. In certain embodiments, the diode assemblies comprise commercially available diodes.

While many photovoltaic modules comprise diode assemblies on exterior surfaces, diode assemblies may also be incorporated into interior portions of photovoltaic modules. Interior diode assemblies can be subject to significant compression forces, particularly in flexible photovoltaic modules, resulting from both compression forces imposed on the exterior of the module and compression forces resulting from expansion and contraction of pottants within the photovoltaic modules during temperature changes.

Compression forces imposed on the exterior of the photovoltaic module, by factors such as adverse weather conditions or by objects striking the module, can transfer those compression forces to the interior diode assembly causing the solder joint to crack or break, compromising the integrity of the module's electrical connections.

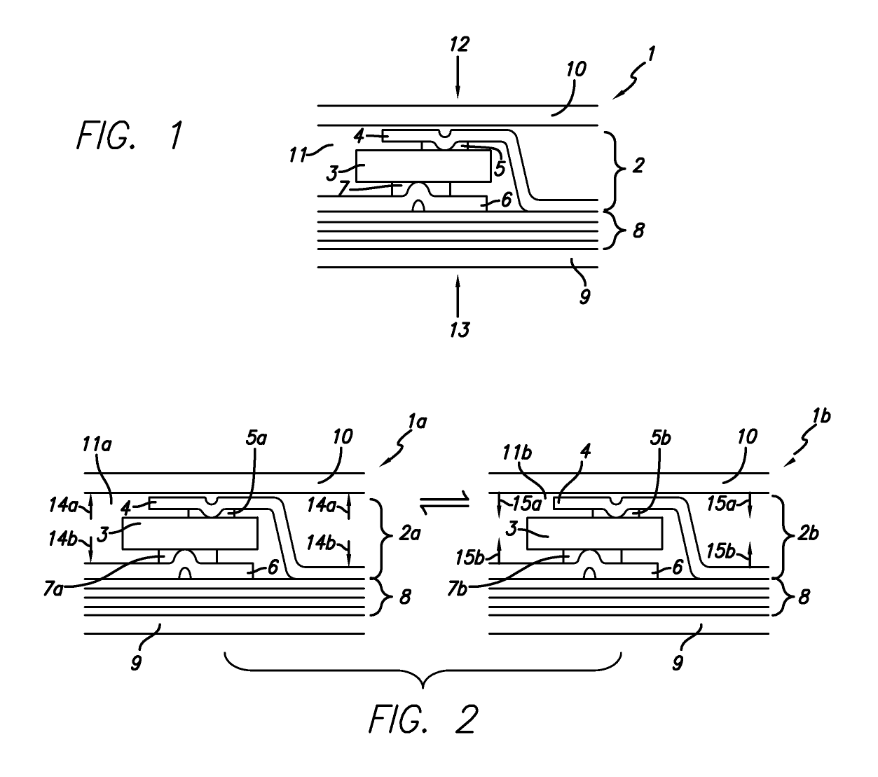

FIG. 1 shows a cross-sectional view of a photovoltaic module 1 comprising a diode assembly 2. The diode assembly 2 comprises a diode 3 in electrical communication with a first lead 4 wherein the diode 3 is affixed to the first lead 4 by a first solder joint 5. The diode 3 is further electrically connected to a second lead 6 and is affixed to the second lead 6 by a solder joint 7. The photovoltaic module 1 further comprises a first encasing layer 9 and a second encasing layer 10. At least one photovoltaic cell 8 is disposed between the at least one photovoltaic cell 8 and the second encasing layer 10. The at least one diode assembly 2 is further electrically connected to the at least one photovoltaic cell 8. The first encasing layer 9 may be rigid or flexible, comprising a transparent material including but not limited to glass, plastic, or fiberglass. The second encasing layer 10 may also be rigid or flexible, comprising materials including but not limited to glass, plastic, metal, or fiberglass. A pottant 11 is disposed between the at least one photovoltaic cell 8 and the second encasing layer 10 filling the space that is not occupied by the at least one diode assembly 2. The pottant 11 is an electrically insulative material that generally covers substantially all of the photovoltaic module area. Examples of pottant materials include polyurethanes, ethylene vinyl acetate (EVA), polyvinyl butyral (PVB), fluoropolymers, silicones, or other electrically insulative materials. In many embodiments, the pottant material is a thermosetting material. Although not depicted, a transparent pottant layer may be present between the at least one photovoltaic cell 8 and the first encasing layer 9. Representative directions of compression forces that may be placed on the exterior of the photovoltaic module are illustrated by arrows 12 and 13. When compression forces are applied to the exterior of the first or second encasing layers 9, 10, those forces may be transferred to the interior of the module, exerting force on the diode assembly 2. These forces may cause cracking or breaking of the first and second solder joints 5, 7.

Interior diode assemblies 2 may also experience mechanical stress during temperature changes. This mechanical stress can be primarily attributed to the expansion and contraction of the pottant 11. The pottant 11 may comprise materials including but not limited to low-density polyethylene that provide electrical insulation to the module's electrical interconnections. A photovoltaic module 1 may be subjected to extreme temperature changes such as dramatic weather changes or during processes such as thermal cycling, a process in which the photovoltaic module is alternately subjected to both high and low temperatures as a method of testing the durability of the module and its components. During these temperature changes, the pottant 11 expands and contracts causing the first and second encasing layers 9, 10 to be forced outward and inward which can place stress on the solder joints 5, 7 of the diode assembly 2, causing them to crack or break if not shielded.

FIG. 2 shows a cross-sectional view of a tensioned photovoltaic module 1a comprising a tensioned diode assembly 2a, including solder joints 5a and 7a, as well as a compressed photovoltaic module 1b comprising a compressed assembly 2b, including solder joints 5b and 7b. The tensioned diode assembly 2a experiences tensile forces due to the expansion of the pottant 11a during temperature increases. Expansion of the pottant 11a causes the first and second encasing layers 9, 10 to be forced outward, placing strain on the diode assembly 2a. The directions of tensile forces imposed by expansion of the pottant 11a are represented by arrows 14a and 14b. Conversely, the compressed diode assembly 2b experiences compression forces due to contraction of the pottant 11b which causes the first and second encasing layers 9, 10 to collapse inward and exert force on the diode assembly 2b. The directions of compression forces imposed by contraction of the pottant 11b are represented by arrows 15a and 15b.

In addition to compression forces, the solder contained in the solder joints is heated during processes such as thermal cycling which may cause the solder to become malleable. Malleable solder is then subject to migration and distortion, particularly in combination with the aforementioned compression forces if no barrier is provided to maintain the solder in its place.

A diode assembly shielding element, such as a localized glass barrier, would provide a convenient and low-cost structure for shielding an interior diode assembly from the aforementioned compression forces as well as inhibit migration of solder during phases of high temperature. Such a structure could re-distribute stress near the diode while being sufficiently thin so as to accommodate the limiting thickness requirements of a thin-film photovoltaic module.

While the photovoltaic module and diode assembly depicted in FIGS. 1 and 2 provide a useful context for discussion of embodiments of the invention, the invention is not limited to the specific configuration of module or diode assembly components depicted. Rather, the diode assembly shielding elements described herein may be used with any interior diode assembly. The location and functionality of the module components may vary based on implementation. For example, in certain embodiments, the diode assembly may be disposed between cell 8 and encapsulating layer 9. In other embodiments, one or more additional module components may be present. Similarly, the diode assembly is not limited to the particular configuration shown. For example, the leadframe may have any appropriate shape or configuration. Moreover, certain embodiments of the invention are not limited to photovoltaic modules, but may be used for shielding any diode or other electrical assembly within planar encasing layers. In many embodiments, the diode assemblies include a diode connected via one or more solder joints to one or more leads. However, other types of diode assemblies including commercially available diodes are also within the scope of the invention.

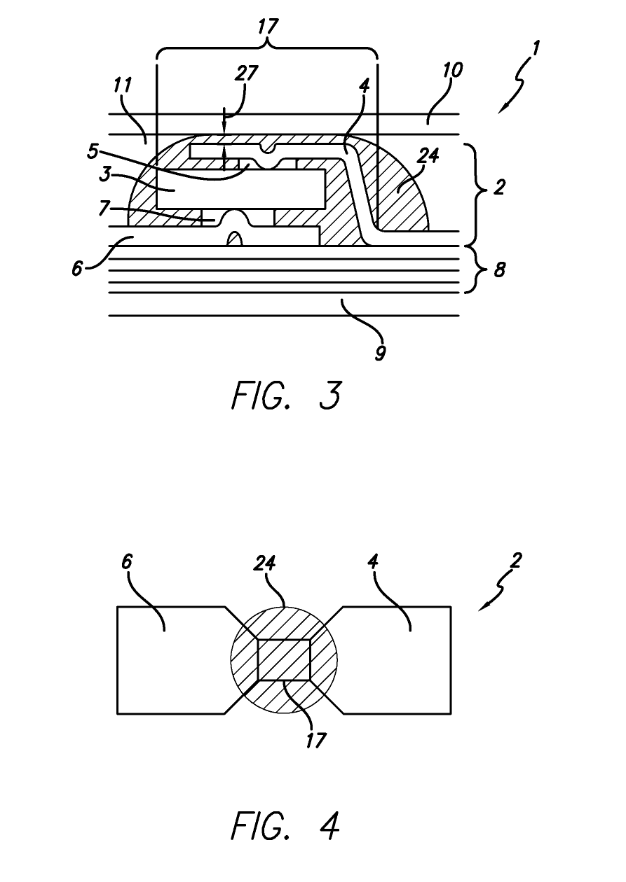

In certain embodiments, shielding of the diode assembly 2 is accomplished by providing a protective shielding element in the form of a glass barrier fully encapsulating the leadframe portion 17 (FIG. 3) of the diode assembly 2 to shield the assembly from force exerted by the first and second encasing layers 9, 10. The leadframe portion 17 (FIG. 3) for the purposes of this embodiment comprises a portion of the diode assembly 2 that includes the entire diode 3, as well as the portion of the first lead 4 that engages the diode 3 up to and including the bent portion 26 and the portion of the second lead 6 that is disposed below the diode 3. A glass barrier would provide a rigid barrier between the diode assembly 2 and the second encasing layer 10. For ease of application, the material used to form the glass barrier could be fluid upon application and rigid/hard upon curing. The fluid material could be applied directly onto the leadframe portion 17 (FIG. 3) after the leadframe portion 17 is formed. A fully encapsulated leadframe portion or fully encapsulated diode assembly generally is a leadframe portion or diode assembly in which at least the portions of the leadframe portion or diode assembly are not in contact with photovoltaic cell 8 or other underlying component.

FIG. 3 is a cross-sectional view of a photovoltaic module 1 comprising a diode assembly 2 with a diode assembly localized glass barrier 24 disposed thereon. The glass barrier fully encapsulates the leadframe portion 17 to minimize the transfer of force applied by the first and second encasing layers 9, 10 and aid in prevention of migration of solder in the solder joints 5, 7. The diode assembly localized glass barrier 24 may comprise materials including but not limited to silicon-based glass materials such as silazanes, siloxanes or derivatives thereof. Application of the diode assembly localized glass barrier 24 may be executed by methods such as dipping, printing, or painting using a glass melt that is allowed to cure on its own or is facilitated by an assisted curing process such as thermal annealing. While the glass barrier is shown in FIG. 3 as merely encasing the lead frame portion of the diode assembly, it is also within the scope of the invention that the glass barrier could encase more area of the assembly up to and including the entire diode assembly.

The diode assembly localized glass barrier 24 could maintain a thickness 27 of 0.0001 to 0.011 inch between the leadframe portion 17 and the second encapsulating layer 10 such as 0.001 and 0.005 inch. Therefore, the overall thickness of the diode assembly localized glass barrier 24 could be between 0.020 and 0.030 inch such as between 0.020 and 0.025 inch.

FIG. 4 is a top view of one embodiment of a diode assembly 2 with a diode assembly localized glass barrier 24 disposed thereon consistent with the configuration shown in FIG. 10. As shown, the glass barrier fully encapsulates the leadframe portion 17 to provide maximum shielding.

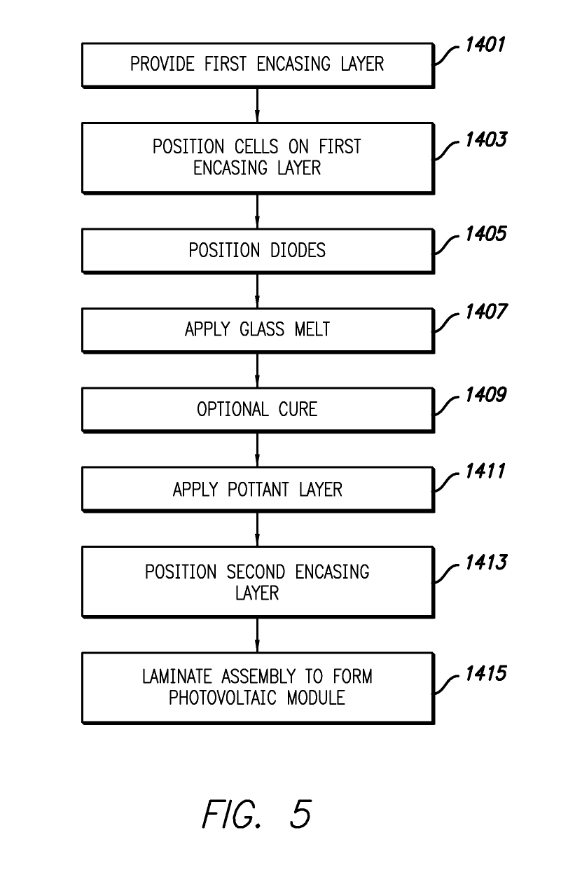

FIG. 5 is a flow chart showing certain operations in a method of fabricating a photovoltaic module including rigid shielding elements according to certain embodiments. A first encasing layer, such as a glass sheet or other transparent layer, is provided. (Block 501). Although not depicted, one or more insulative or other materials may be placed on or applied to the first encasing layer at this point. The photovoltaic cells are then positioned on the first encasing layer. (Block 503). One or more diode assemblies are then positioned. (Block 505). According to various embodiments, the diode assemblies may be positioned on or adjacent to the photovoltaic cells, so long as they are electrically connected to the photovoltaic cells. In certain embodiments, multiple diode assemblies connected via connectors or a strip of metal, polymer or other material are laid out over the cells to make contact with the cell backsides. The fluid glass material is then applied, e.g., by applying the material to each of the diode assemblies to encapsulate the assemblies or leadframe portions thereof as in FIGS. 3 and 4. (Block 507). The glass barrier material may optionally be cured. (Block 509). In certain embodiments, the glass barrier material may be applied to the diode assembly prior to positioning the diode assemblies on the photovoltaic cells. Also in certain embodiments, multiple low durometer shielding elements may be connected, e.g. via a polymer strip or other connector, for easy placement. A pottant layer is then applied. (Block 511). In certain embodiments the pottant layer is applied as a thermoplastic sheet that is heated in a subsequent processing operation to fill the space around the diode assemblies and glass barrier as described above with respect to FIGS. 1 and 2. The second encasing layer is then positioned. (Block 513). The entire assembly is then laminated to create the photovoltaic module. (Block 515).

While the present invention has been described with reference to preferred embodiments, those skilled in the art will recognize that changes may be made in form and detail without departing from the spirit and scope of the invention.

What is claimed is:

1. A method of shielding a diode assembly of a photovoltaic module from compression forces, the method comprising:
providing a photovoltaic module comprising at least one diode assembly; and
providing at least one diode assembly localized glass barrier configured to protect the diode assembly from compressive or tensile forces applied to the module.

2. The method as recited in claim 1, wherein the glass barrier comprises a silazane or siloxane.

3. The method as recited in claim 2, wherein the glass barrier comprises a siloxane.

4. The method as recited in claim 1, wherein the step of providing at least one diode assembly localized glass barrier comprises:
depositing a glass melt on a leadframe portion so the glass melt fully encapsulates the leadframe portion; and
allowing the glass melt to cure.

5. The method as recited in claim 4, wherein the step of depositing a glass melt on a leadframe portion comprises dipping, printing, or painting.

6. The method as recited in claim 4, wherein the step of allowing the glass melt to cure includes thermal annealing the glass melt.

7. A photovoltaic module comprising:
a first encasing layer;
a second encasing layer;
at least one photovoltaic cell disposed between the first and second encasing layers;
at least one diode assembly disposed between the at least one photovoltaic cell and the second encasing layer; and
a localized glass barrier configured to protect the diode assembly from compressive or tensile forces applied to the module disposed between the at least one photovoltaic cell and the second encasing layer.

8. The photovoltaic module of claim 7, wherein the glass barrier comprises a silazane or siloxane.

9. The photovoltaic module of claim 8, wherein the glass barrier comprises a siloxane.

10. The photovoltaic module of claim 7, wherein the glass barrier fully encapsulates a leadframe portion of a diode assembly.

11. The photovoltaic module of claim 7, wherein the glass barrier has a thickness between 0.020 and 0.030 inch.

12. The photovoltaic module of claim 7, wherein the glass barrier has a thickness between 0.020 and 0.025 inch.

13. The photovoltaic module of claim 7, further comprising a pottant disposed between the at least one photovoltaic cell and the second encasing layer.

14. A method of making a photovoltaic module comprising a diode assembly protected by a glass barrier, the method comprising:
providing a photovoltaic assembly by:
providing a first encasing layer,
positioning cells on a first encasing layer,
providing protected diode assemblies,
applying a pottant layer;
positioning a second encasing layer;
laminating the photovoltaic assembly; and
wherein the protected diode assemblies comprise at least one localized glass barrier.

15. The method as recited in claim 14, wherein the glass barrier comprises a silazane or siloxane.

16. The method as recited in claim 15, wherein the glass barrier comprises a siloxane.

17. The method as recited in claim 14, wherein the step of providing at least one diode assembly localized glass barrier comprises:
depositing a glass melt on a leadframe portion so the glass melt fully encapsulates the leadframe portion; and
allowing the glass melt to cure.

18. The method as recited in claim 14, wherein the step of depositing a glass melt on a leadframe portion comprises dipping, printing, or painting.

19. The method as recited in claim 4, wherein the step of allowing the glass melt to cure includes thermal annealing the glass melt.
